(19) United States
(12) Patent Application Publication
(10) Pub. No.: US 2026/0324002 A1
(43) Pub. Date: Oct. 15, 2026

(54) SEMICONDUCTOR STRUCTURE HAVING RECESSED CHANNEL UNIT AND METHOD FOR MANUFACTURING THE SAME

(71) Applicant: TAIWAN SEMICONDUCTOR MANUFACTURING COMPANY, LTD., Hsinchu (TW)

(72) Inventors: Yu-Chien CHIU, Hsinchu (TW); Chen-Jun WU, Hsinchu (TW); Ya-Yun CHENG, Hsinchu (TW); Wen-Ling LU, Hsinchu (TW); Chung-Wei WU, Hsinchu (TW); Zhiqiang WU, Hsinchu (TW)

(73) Assignee: TAIWAN SEMICONDUCTOR MANUFACTURING COMPANY, LTD., Hsinchu (TW)

(21) Appl. No.: 19/176,762

(22) Filed: Apr. 11, 2025

(51) Int. Cl. H10D 30/67; H10B 12/00; H10D 30/01

(52) U.S. Cl. CPC H10D 30/6755; H10B 12/02; H10B 12/315; H10D 30/0312; H10D 30/6757

(57) ABSTRACT

A method for manufacturing a semiconductor structure includes: forming a lower electrode unit on a base structure; forming a gate structure over the lower electrode unit, the gate structure being formed with a cavity above the lower electrode unit; forming a channel unit, which includes forming an outer channel layer and an inner channel layer along an inner surface of the cavity, the outer channel layer and the inner channel layer having different compositions; performing a recessing process on the channel unit, and after the recessing process, an upper end of the outer channel layer being located at a level higher than a level of an upper end of the inner channel layer; and after the recessing process, forming an upper electrode unit connected to both the outer channel layer and the inner channel layer.

### BACKGROUND

A one-transistor-one-capacitor (1T1C) memory structure includes one thin film transistor and one capacitor. In order to enhance write speed and read speed of the memory structure, the industry advocates reduction of contact resistance among different elements in the memory structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 31 are schematic views illustrating intermediate stages of the method for manufacturing the semiconductor structure in accordance with some embodiments.

FIG. 32 is a diagram showing device currents of semiconductor structures at different gate voltages in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±30%, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The present disclosure is directed to a semiconductor structure having a recessed channel unit, and method for manufacturing the same. The semiconductor structure includes a channel unit, a gate structure surrounding the channel unit, a lower electrode, and an upper electrode. The lower electrode and the upper electrode are respectively located below and above the channel unit, and are connected to the channel unit. The channel unit includes an outer channel layer and an inner channel layer that have different compositions. The outer channel layer is formed on and along an inner surface of the gate structure and on a top surface of the lower electrode. The inner channel layer is formed on the outer channel layer opposite to the gate structure and the lower electrode. An upper end of the outer channel layer is located at a level higher than a level of an upper end of the inner channel layer. Such channel unit may be referred to as a recessed channel unit, which is formed by a recessing process performed on the channel unit during manufacturing process of the semiconductor structure. During the recessing process, the inner channel layer exhibits an etching rate higher than that of the outer channel layer, resulting in the inner channel layer being more recessed than the outer channel layer. As such, the recessed channel unit has an increased top surface area that is to be connected to the upper electrode, thus a reduced contact resistance between the recessed channel unit and the upper electrode. Therefore, the semiconductor structure of the present disclosure has an enhanced device performance, e.g., an improved device current, which is beneficial to increase the write and read speed of the semiconductor structure serving as a 1T1C memory structure.

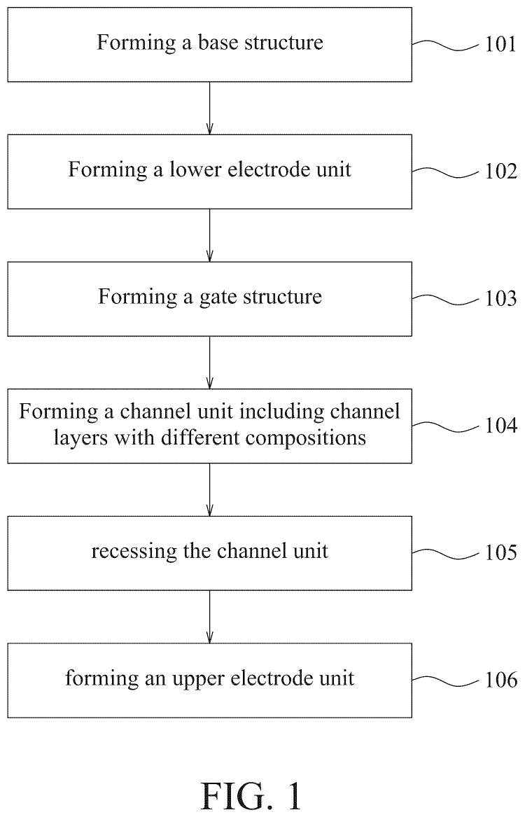

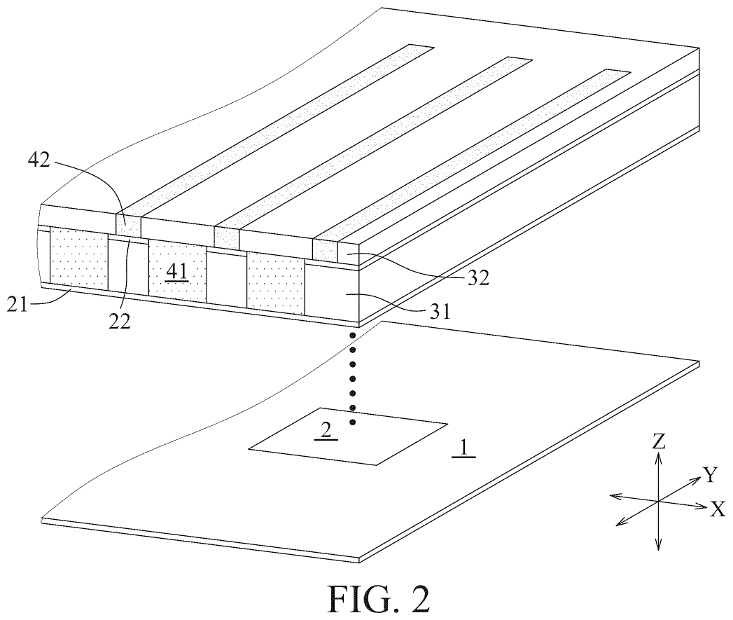

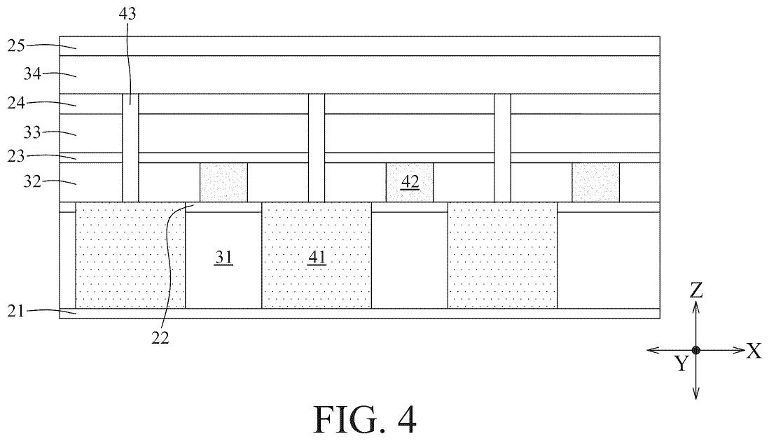

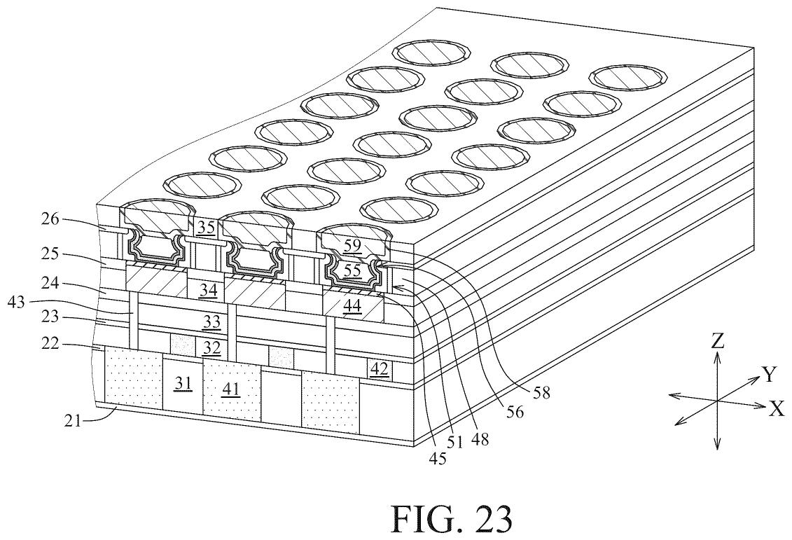

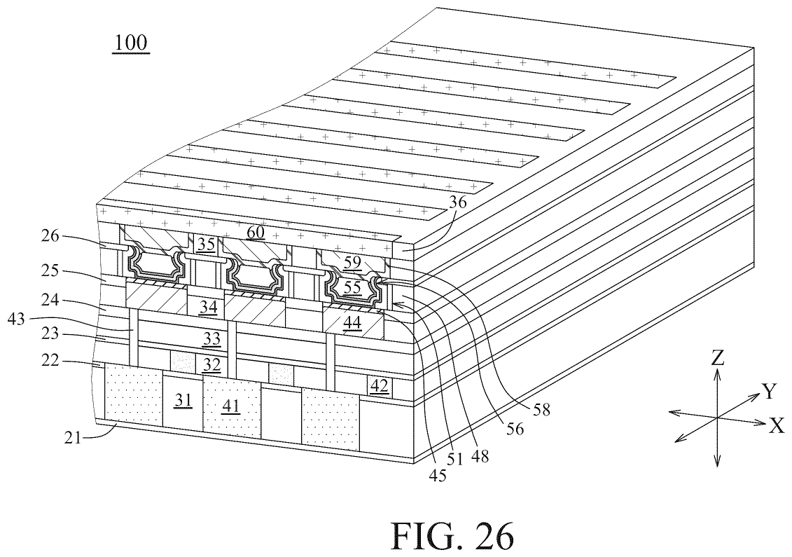

FIG. 1 is a flow diagram illustrating a method for manufacturing the semiconductor structure (for example, the semiconductor structure 100 shown in FIG. 26) in accordance with some embodiments. FIGS. 2 to 27 illustrate schematic views of intermediate stages of the method in accordance with some embodiments. Steps illustrated in FIGS. 2 to 27 are also illustrated schematically in the flow diagram shown in FIG. 1. Some repeating structures are omitted in FIGS. 2 to 27 for the sake of brevity. Additional steps can be provided before, after or during the method, and some of the steps described herein may be replaced by other steps or be eliminated. FIGS. 2, 3, 6, 8, 11, 16, 23, 26, 27 are perspective views of the structure, while FIGS. 4, 5, 7, 9, 10, 12, 13, 14, 15, 18, 19, 21, 22, 25 are cross-sectional views (along an X direction) of the structure.

Referring to FIG. 2, conductive elements 42 are formed over memory elements 41. The conductive elements 42 and the memory elements 41 are formed over a substrate 1.

The substrate 1 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The substrate 1 may be formed with an n-type well (not shown) having an n-type conductivity and/or a p-type well (not shown) having a p-type conductivity. Each of the n-type well and the p-type well may be formed by introducing an n-type impurity or a p-type impurity into the substrate 1 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some embodiments, the starting substrate 1 may be a bulk silicon substrate, a silicon-on-insulator (SOI) substrate, or a germanium-on-insulator (GOI) substrate. In some embodiments, the substrate 1 may be made of silicon. Other suitable materials for forming the substrate 1 are within the contemplated scope of the present disclosure.

In some embodiments, semiconductor devices 2 (one of which is shown) may be formed over the substrate 1. The semiconductor devices 2 are electrically connected to any elements formed in subsequent steps. The semiconductor devices 2 may be any suitable devices, such as a transistor, a capacitor, a resistor, a decoder, an amplifier, other suitable devices, and combinations thereof, but are not limited thereto. Please note that in subsequent figures, the substrate 1 and the semiconductor devices 2 are omitted for the sake of brevity.

In some embodiments, an etch stop layer (ESL) 21, an interlayer dielectric (ILD) 31 and an ESL 22 are subsequently formed above the substrate 1 and the semiconductor devices 2. Next, the memory elements 41 are formed in the ILD 31, and are exposed from the ESL 22. An ILD 32 is then formed over the ESL 22 and the memory elements 41. Thereafter, the conductive elements 42 are formed in the ILD 32, and are displaced from the memory elements 41.

In some embodiments, the ESLs 21, 22, and any ESLs described in subsequent steps, may include or be made of aluminum oxide, aluminum nitride, aluminum oxycarbide, other suitable materials, or combinations thereof, but is not limited thereto. In certain embodiments, the ILD 31, 32, and any ILDs described in subsequent steps, may include or be made of a dielectric material such as silicon oxide, silicon nitride, phosphosilicate glass, borophosphosilicate glass, spin-on glass, fluorosilicate glass, carbon-doped silicon oxide, xerogel, aerogel, parylene, divinylsiloxane-bis-benzocyclobutene-based dielectric material, polyimide, or combinations thereof, but are not limited thereto. Each of the ESLs 21, 22, and the ILDs 31, 32 may be formed using any suitable deposition processes, such as physical vapor deposition (PVD), chemical vapor deposition (CVD), atomic layer deposition (ALD), other suitable processes, or combinations thereof, but are not limited thereto. In the following description, a deposition process, unless otherwise stated or defined in this disclosure, may be performed in a way similar to the above-mentioned ones. Other suitable materials and/or processes for forming the ESLs 21, 22, and the ILDs 31, 32 are within the contemplated scope of the present disclosure.

In some embodiments, each of the memory elements 41 may be a capacitor, but is not limited thereto. The memory elements 41 are formed to be spaced apart from each other in the X direction. Each of the memory elements 41 extend lengthwise in a Y direction that is different from (e.g., perpendicular to) the X direction. Each of the memory elements 41 may include two electrodes (not shown) that are separated from each other by a dielectric part (not shown). The electrodes may include or be made of tantalum nitride (TaN), titanium nitride (TiN), tungsten (W), aluminum (Al), polysilicon (Poly), other suitable materials, or combinations thereof. The dielectric part may include or be made of a dielectric material having high dielectric constant, such as zirconium oxide (ZrO), hafnium zirconium oxide (HZO), zirconium aluminum oxide (ZAO), silicon doped hafnium oxide (HSO), other suitable materials, or combinations thereof.

In some embodiments, each of the conductive elements 42 may include or made of a conductive material, such as tungsten (W), titanium nitride (TiN), ruthenium (Ru), tantalum nitride (TaN), molybdenum (Mo), tungsten nitride (WN), copper (Cu), titanium (Ti), cobalt (Co), aluminum (Al), other suitable materials, or combinations thereof. The conductive elements 42 may be formed in the ILD 32 by any suitable processes. For example, a patterning process is performed to form a plurality of grooves (not shown) in the ILD 32 to expose the ESL 22. Next, the grooves are filled with a material for forming the conductive elements 42 using CVD, ALD or other suitable deposition processes. Thereafter, a planarization process (e.g., chemical mechanical polishing (CMP)) is performed to remove an excess amount of the material for forming the conductive elements 42. In accordance with some embodiments, the conductive elements 42 may each serve as a word line (WL).

The patterning process for patterning the ILD 32 may include a photolithography process followed by an etching process. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, a photolithography process, and/or an etching process, unless otherwise stated or defined in this disclosure, may be performed in a way similar to the above-mentioned ones.

Other suitable configurations and/or processes for forming the ESLs 21, 22, ILDs 31, 32, memory elements 41 and the conductive elements 42 are within the contemplated scope of the present disclosure.

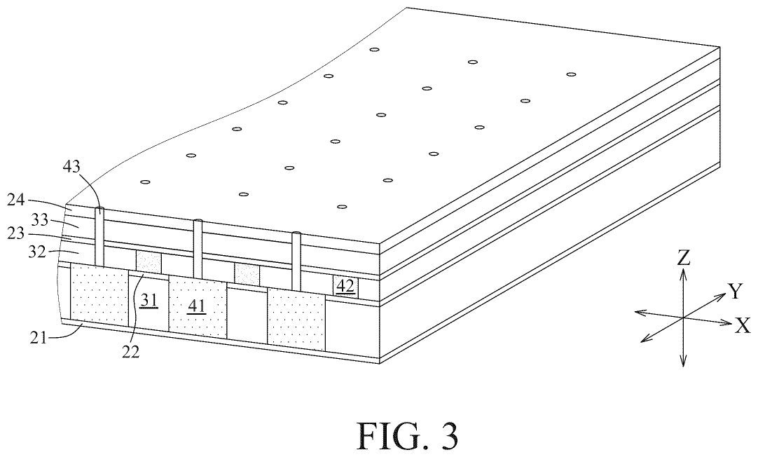

Referring to FIG. 3, vias 43 are formed and connected to the memory elements 41, respectively. In some embodiments, in each of the memory elements 41, one of the two electrodes is electrically connected to a respective one of the vias 43, and the other one of the two electrodes is electrically connected to a suitable element, for example, a respective one of the semiconductor devices 2 (one of which is shown in FIG. 2).

The vias 43 may be formed by: forming an ESL 23, an ILD 33 and an ESL 24 over the conductive elements 42 and the ILD 32, performing a suitable patterning process to pattern the ESL 23, the ILD 33 and the ESL 24 and to form through holes (not shown) exposing the memory elements 41, respectively; filling the through holes with a conductive material using any suitable deposition processes, followed by a planarization process (e.g., CMP, but is not limited thereto) to remove an excess amount of the conductive material, thereby obtaining the vias 43. In some embodiments, the conductive material for forming the vias 43 may include or be made of a material similar to that of the conductive elements 42, but is not limited thereto. Other suitable materials and/or processes for forming the vias 43 are within the contemplated scope of the present disclosure. The structure shown in FIG. 3 may be considered as a base structure for being subjected to further processes. In some other embodiments, the base structure may have other suitable configurations. Step 101 in the flow diagram shown in FIG. 1 is exemplified by the structures shown in FIGS. 2 to 3.

Referring to FIG. 4, an ILD 34 and an ESL 25 are formed over the ESL 24 using any suitable deposition processes.

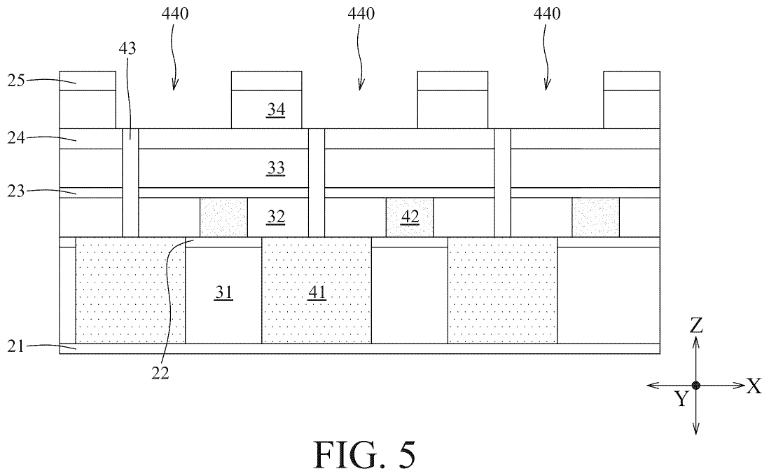

Referring to FIG. 5, openings 440 are formed in the ILD 34 and the ESL 25, and exposing the vias 43, respectively. The openings 440 may be formed using any suitable patterning processes including one or multiple etching processes, but are not limited thereto.

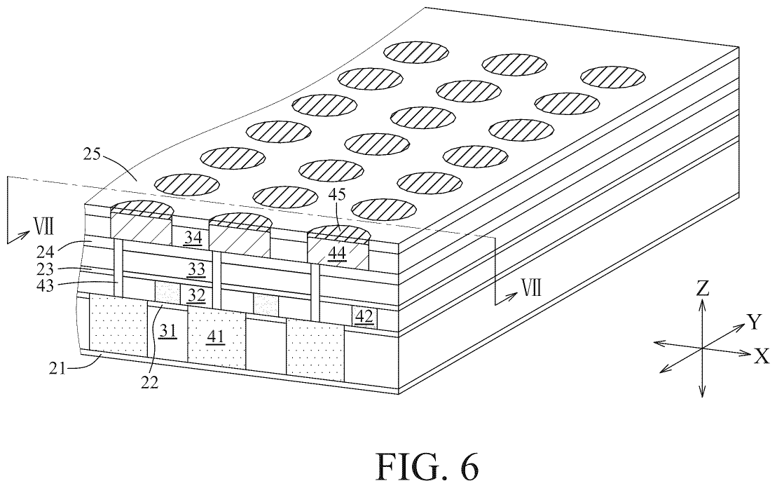

Referring to FIG. 6, lower electrode units are formed in the openings 440, respectively. In some embodiments, lower electrodes 44 are first formed, and hydrogen absorption layers 45 are formed on the lower electrodes 44, respectively. In other words, each of the lower electrode units includes one of the lower electrodes 44 and a respective one of the hydrogen absorption layers 45.

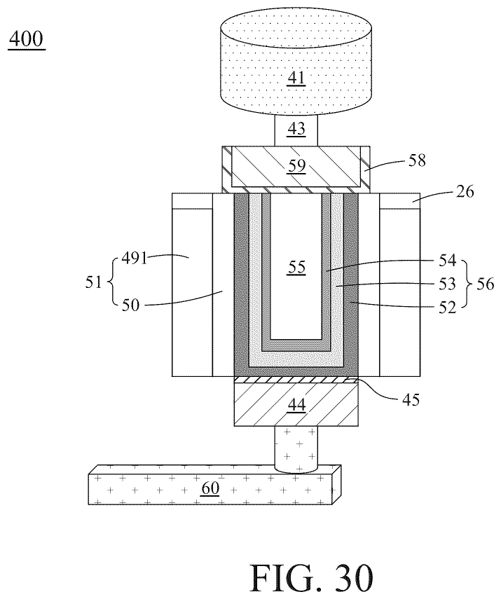

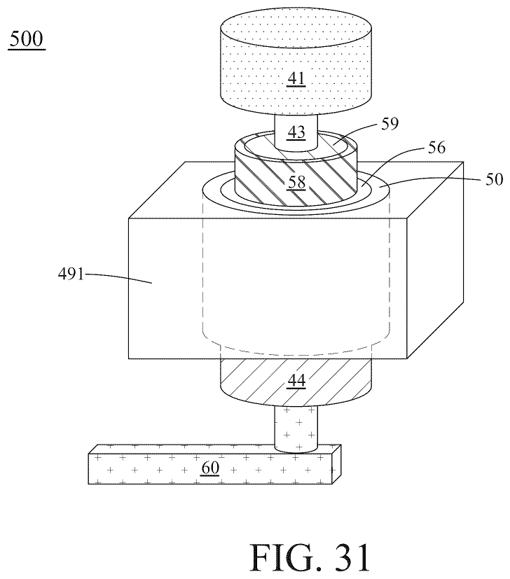

The lower electrodes 44 are configured as source/drain electrodes, depending on product designs. In accordance with some embodiments shown in FIGS. 2 to 29, the lower electrodes 44 serve as source electrodes of the semiconductor structure 100 for connecting to the memory elements 41. In other embodiments, the lower electrodes 44 serve as drain electrodes of the semiconductor structure 100 for connecting to bit lines (e.g., one of which is exemplified as a conductive feature 60 shown in FIGS. 30 and 31). The lower electrodes 44 may include or be made of tantalum nitride (TaN), titanium nitride (TiN), tungsten (W), aluminum (Al), polysilicon (Poly), ruthenium (Ru), cobalt (Co), copper (Cu), indium tin oxide (ITO), other suitable materials, or combinations thereof. The lower electrodes 44 may be formed in the openings 440 by performing a deposition process over the structure shown in FIG. 5, followed by an etching back process. Therefore, an upper surface of each of the lower electrodes 44 is at a level lower than a level of an upper surface of the ESL 25.

The hydrogen absorption layers 45 are each formed to cover a respective one of the lower electrodes 44. The hydrogen absorption layers 45 are configured to block hydrogen, if any, diffusing from the lower electrodes 44 through the hydrogen absorption layers 45 into any elements formed thereon. The hydrogen absorption layers 45 may include or be made of, indium oxide (TiO), titanium oxide (TiO), indium tin oxide (ITO), cerium oxide (CeO), zinc oxide (ZnO), indium gallium zinc oxide (IGZO), other suitable materials, or combinations thereof. In some embodiments, the hydrogen absorption layers 45 are formed by depositing a hydrogen absorption material for forming the hydrogen absorption layers 45 over the lower electrodes 44 using any suitable deposition processes, followed by a suitable process (e.g., CMP) to remove the hydrogen absorption material on the ESL 25. Other suitable configurations and/or processes for forming the lower electrodes 44 and/or the hydrogen absorption layers 45 are within the contemplated scope of the present disclosure. Step 102 in the flow diagram shown in FIG. 1 is exemplified by the structures shown in FIGS. 5 to 6. In other embodiments, the hydrogen absorption layers 45 may be omitted.

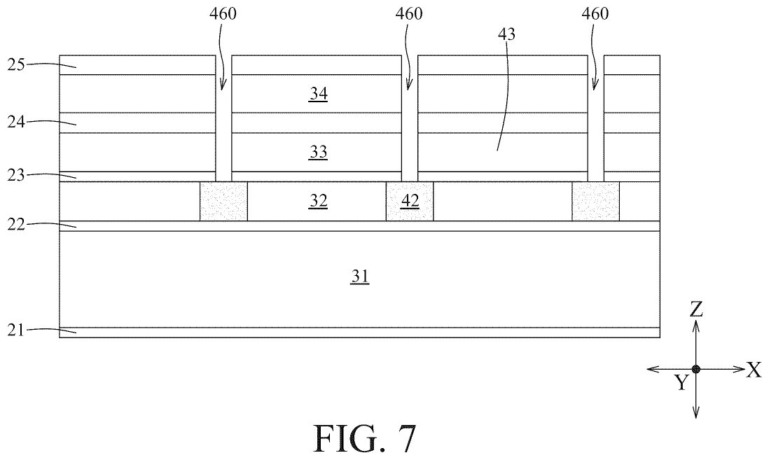

FIG. 7 illustrates a process subsequent to the process described with reference to FIG. 6, by showing a cross-sectional view taken along line VII-VII shown in FIG. 6. Referring to FIG. 7, through holes 460 are formed to penetrate through the ILDs 33, 34 and the ESLs 23, 24, 25, so as to expose the conductive elements 42, respectively.

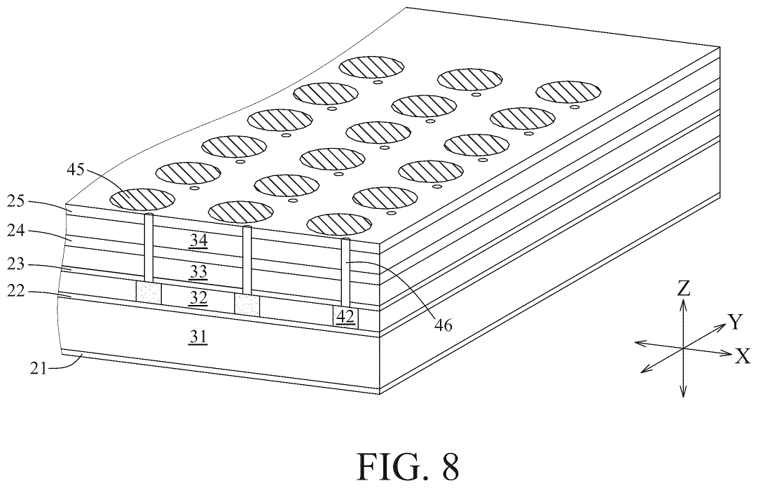

Referring to FIG. 8, vias 46 are formed by: depositing a conductive material for forming the vias 46 over the structure shown in FIG. 7 to fill the through holes 460; and removing an excess amount of the conducting material. The conductive material for forming the vias 46 may be similar to that of the conductive elements 42. The vias 46 are connected to the conductive elements 42. In accordance with some embodiments, the vias 46 may each serve as a WL via. In the exemplary embodiments shown in FIGS. 5 to 8, the lower electrodes 44 are formed prior to forming the vias 46. In some other embodiments, the vias 46 are formed prior to forming to the lower electrodes 44.

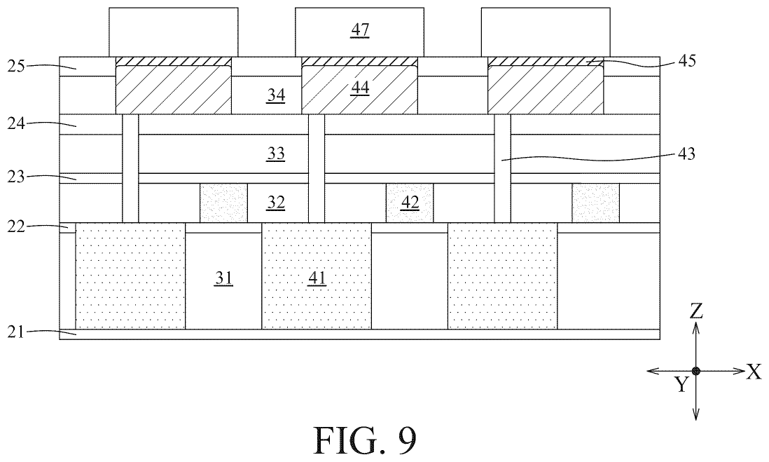

FIG. 9 is a cross-sectional view similar to FIG. 5, but further illustrating the lower electrodes 44, the hydrogen absorption layers 45 and sacrificial parts 47. Referring to FIG. 9, after forming the WL vias 46 (see FIG. 8), the sacrificial parts 47 are respectively formed on the hydrogen absorption layers 45 opposite to the lower electrodes 44. The sacrificial parts 47 are configured to cover the lower electrodes 44 but the WL vias 46 are exposed from the sacrificial parts 47. The sacrificial parts 47 are spaced apart from each other in both the X and Y directions. In some embodiments, the sacrificial parts 47 are arranged in columns and rows. The columns of the sacrificial parts 47 are displaced from each other in the X direction, and the rows of the sacrificial parts 47 are displaced from each other in the Y direction. In certain embodiments, the sacrificial parts 47 may also cover portions of the ESL 25 that surround the lower electrodes 44. In some embodiments, the sacrificial parts 47 include or made of a dielectric material, such as, silicon nitride, or a nitride-based dielectric material, but are not limited thereto. In some embodiments, the sacrificial parts 47 are formed by depositing a sacrificial dielectric material over the hydrogen absorption layers 45 and the ESL 45 using a suitable deposition process, followed by a suitable patterning process. Other suitable materials and/or processes for forming the sacrificial parts 47 are within the contemplated scope of the present disclosure.

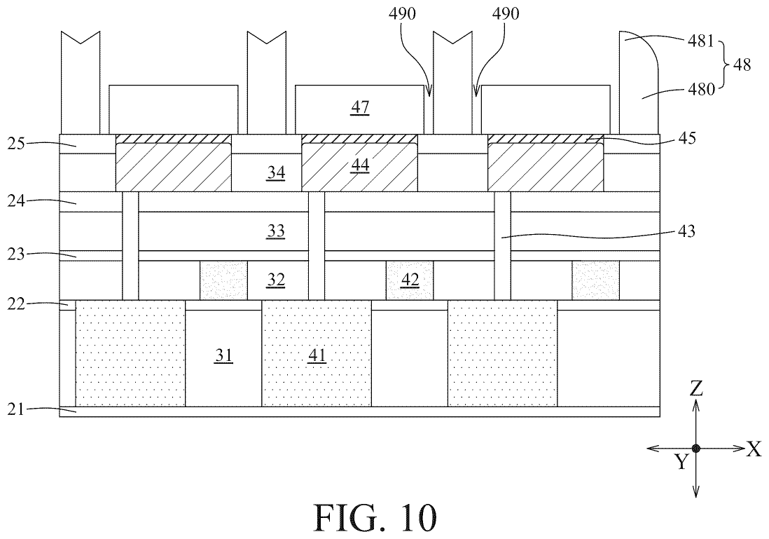

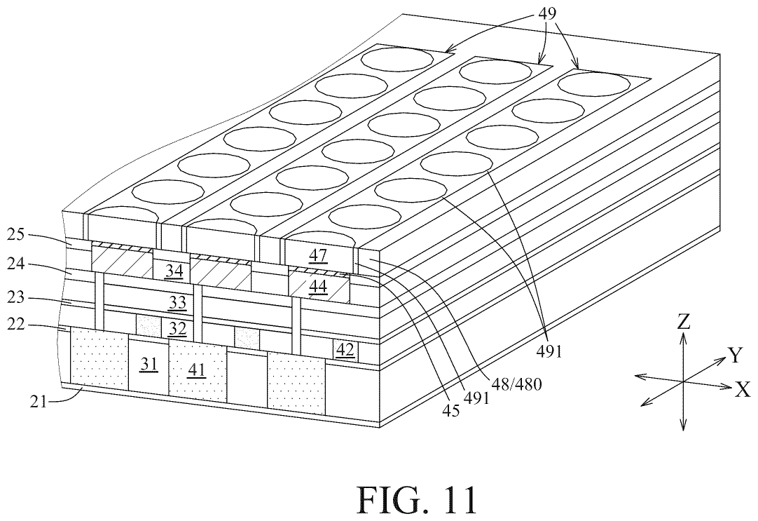

Referring to FIG. 10, an isolation layer 48 is formed over the ESL 25 and surrounding the sacrificial parts 47. The vias 46 shown in FIG. 8 are exposed from the isolation layer 48. The isolation layer 48 is spaced apart from the sacrificial parts 47 by gaps 490. In some embodiments, the isolation layer 48 includes isolation parts 480 and protruded parts 481. The isolation parts 480 are disposed to alternate with the columns of the sacrificial parts 47 in the X direction (see also FIG. 11). The protruded parts 481 are respectively protruded from the isolation parts 480. Examples of the dielectric material for forming the isolation layer 48 are similar to those of the ILDs 21, 22, and thus are not repeated for the sake of brevity. In some embodiments, the isolation layer 48 may include or be made of a dielectric material that is different from the dielectric material of the sacrificial parts 47. In some embodiments, the isolation layer 48 is formed by a suitable deposition process, followed by a patterning process. Other suitable materials and/or processes for forming the isolation layer 48 are within the contemplated scope of the present disclosure.

Referring to FIG. 11, gate electrodes 49 are formed by depositing a gate electrode material layer (not shown) over the structure shown in FIG. 10 using a suitable deposition process to fill the gaps 490, followed by a planarization process (e.g., CMP, but is not limited thereto). In the planarization process, an excess amount of the gate electrode material layer is removed, so as to form the gate electrodes 49 in the gaps 490, respectively. In addition, the protruded parts 481 of the isolation layer 48 are also removed, and the remaining isolation parts 480 of the isolation layer 48 have a top surface substantially flush with top surfaces of the gate electrodes 49. The gate electrodes 49 are spaced apart from each other by the remaining isolation layer 48. Each of the gate electrodes 49 surrounds a corresponding column of the sacrificial parts 47. In other words, each of the gate electrodes 49 includes gate electrode portions 491 respectively surrounding the corresponding column of the sacrificial parts 47. In addition, each of the gate electrode portions 491 covers a respective one of the WL vias 46 (see FIG. 8). In some embodiments, the gate electrodes 49 may include or be made of tantalum nitride (TaN), titanium nitride (TiN), tungsten (W), aluminum (Al), polysilicon (Poly), or combinations thereof, but are not limited thereto. Other suitable materials and/or processes for forming the gate electrodes 49 are within the contemplated scope of the present disclosure.

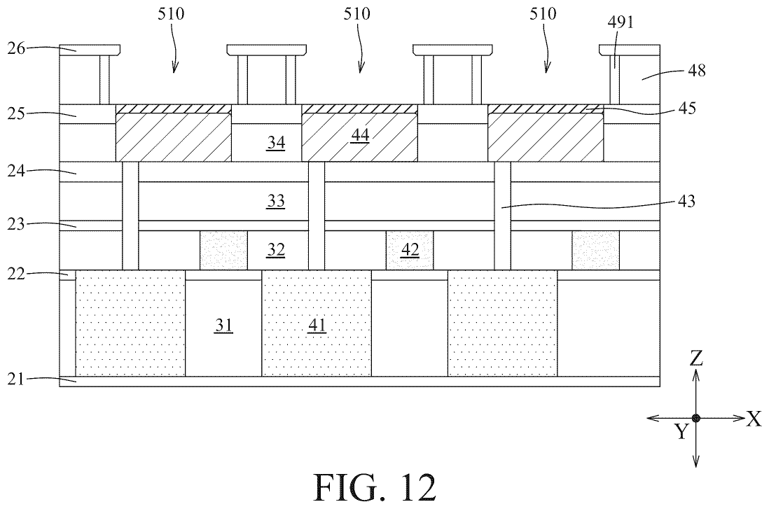

Referring to FIG. 12, a patterned ESL 26 is formed over the structure shown in FIG. 11, and the sacrificial parts 47 are removed through the patterned ESL 26, so as to form cavities 510.

The patterned ESL 26 may be formed by depositing a dielectric material layer using a suitable deposition process, followed by a patterning process. After the patterning process, the sacrificial parts 47 are exposed, and then removed using a suitable etching process. Through the patterned ESL 26, each of the cavities 510 exposes one of the gate electrode portions 491 (see also FIG. 11), the ESL 25, and the hydrogen absorption layer 45 of a corresponding one of the lower electrode units.

In some embodiments, the ESL 26 has parts that overhang the ESL 25 and/or the lower electrodes 44. For instance, as shown in FIG. 12, for each of the cavities 510, a width (measured along the X direction) at the level of the patterned ESL 26 is smaller than a width at the level of the gate electrode portions 491. In other embodiments, for each of the cavities 510, a width (measured along the X direction) at the level of the patterned ESL 26 is similar to a width at the level of the gate electrode portions 491.

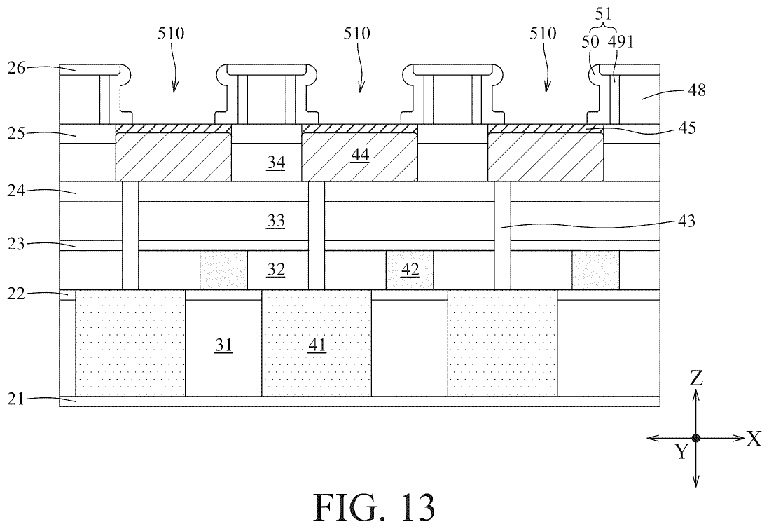

Referring to FIG. 13, gate dielectric layers 50 are respectively formed in the cavities 510.

In some embodiments, the gate dielectric layers 50 may be formed by forming a gate dielectric material layer (not shown) over the structure shown in FIG. 12 using a suitable deposition process, followed by any suitable etching process (e.g., anisotropic etching process) to remove horizontal portions of the gate dielectric material layer, e.g., those on top surface of the ESL 26 and on top surfaces of the hydrogen absorption layers 45. After forming the gate dielectric layers 50, each of the gate electrode portions 491 may be entirely covered by a corresponding one of the gate dielectric layers 50, and thus may not be accessible through a corresponding one of the cavities 510.

The gate dielectric layers 50 may include or be made of a dielectric material, such as silicon oxide, silicon nitride, silicon oxynitride, silicon carbonitride, silicon oxycarbide, silicon oxycarbonitride, silicon carbide, or combinations thereof, but are not limited thereto. In other embodiments, the gate dielectric layers 50 may include or be made of a high k dielectric material, such as hafnium oxide, zirconium oxide, zirconium aluminum oxide, hafnium aluminum oxide, hafnium silicon oxide, aluminum oxide, hafnium silicon oxynitride, hafnium tantalum oxide, hafnium titanium oxide, hafnium zirconium oxide, zirconium silicate, zirconium aluminate, titanium oxide, hafnium oxide -aluminum oxide alloy, or combinations thereof.

In some embodiments, the gate dielectric layers 50 are formed in a conformal manner, e.g., along the overhanging parts of the ESL 26, the gate electrodes 49, the ESL 25 and the hydrogen absorption layers 45. After forming the gate dielectric layers 50, the hydrogen adsorption layers 45 are each exposed from a corresponding one of the gate dielectric layers 50. In some embodiments, for each of the hydrogen adsorption layers 45, a periphery region thereof is covered by the corresponding gate dielectric layer 50, while a central region thereof is exposed.

Other suitable materials and/or configurations and/or processes for forming the gate dielectric layers 50 are within the contemplated scope of the present disclosure.

After forming the gate dielectric layers 50, the gate structures 51 are obtained. Each of the gate structures 51 includes one of the gate dielectric layers 50 and a corresponding one of the gate electrode portions 491. Each of the gate structures 51 is formed with a corresponding one of the cavities 510, which is located above a corresponding one of the lower electrodes 44. Step 103 in the flow diagram shown in FIG. 1 is exemplified by the structures shown in FIGS. 9 to 13.

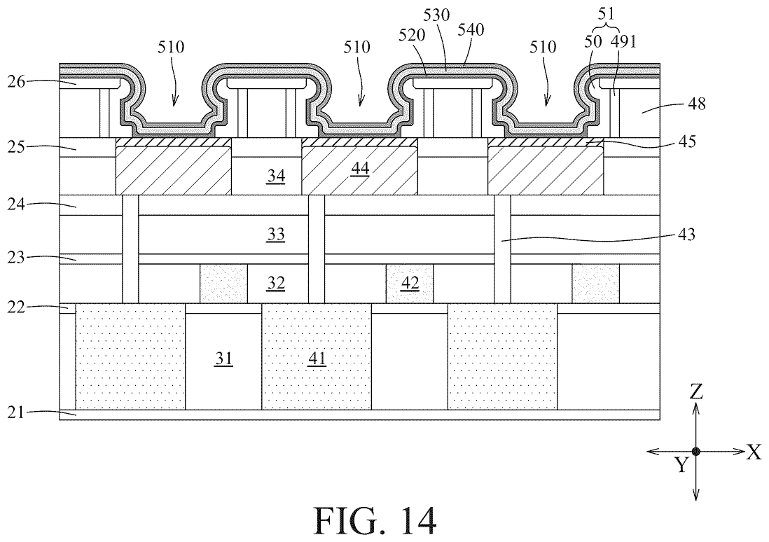

Referring to FIG. 14, two or more channel material layers having different compositions are formed over the structure shown in FIG. 13 and along inner surfaces of the cavities 510.

The channel material layers may be formed by any suitable deposition processes, such as CVD, ALD, but are not limited thereto. In some embodiments, the channel material layers are formed in a conformal manner along the inner surfaces of the cavities 510 (i.e., along the gate structures 51 and the exposed hydrogen absorption layers 45), as well as on the ESL 26. The channel material layers may include or may be made of a metal oxide, depending on desired properties of the semiconductor structure 100. For instance, when the semiconductor structure 100 is designed to have an n-type channel, the channel material layers may each include or be made of indium gallium zinc oxide (IGZO), zinc oxide (ZnO), indium oxide (In₂O₃), tin (IV) oxide (SnO₂), indium zinc oxide (IZO), gallium oxide (GaO), indium gallium oxide (IGO), or other suitable materials, or combinations thereof. The channel material layers for forming the n-type channel may be doped with dopants such as nitrogen (N), fluorine (F), aluminum (Al), hafnium (Hf), magnesium (Mg), silicon (Si), titanium (Ti), tungsten (W), yttrium (Y), zirconium (Zr), boron (B), hydrogen (H), lithium (Li), nickel (Ni), potassium (K) or combinations thereof. When the semiconductor structure 100 is designed to have a p-type channel, the channel material layers may each include or be made of nickel oxide (NiO), copper oxide (Cu₂°), copper aluminum oxide (CuAlO₂), copper gallium oxide (CuGaO₂), copper indium oxide (CuInO₂), strontium copper oxide (SrCu₂O₂), tin (II) oxide (SnO), or other suitable materials, or combinations thereof. The channel material layers for forming the p-type channel may be doped with dopants such as potassium (K), rubidium (Rb), titanium (Ti), phosphorus (P), tantalum (Ta), sulphur (S), fluorine (F), sodium (Na), cesium (Cs), germanium (Ge), or combinations thereof. Other suitable materials and/or processes for forming the channel material layers are within the contemplated scope of the present disclosure. It is noted that, by varying composition of each of the channel material layers, carrier concentration of each of the channel material layers may also be varied.

In accordance with some embodiments, as shown in FIG. 14, three of the channel material layers (but are not limited thereto), namely, an outer channel material layer 520, a middle channel material layer 530, and an inner material layer 540 are sequentially formed on the inner surfaces of the cavities 510. Please note that the number of the channel material layers may be adjusted according to practical needs.

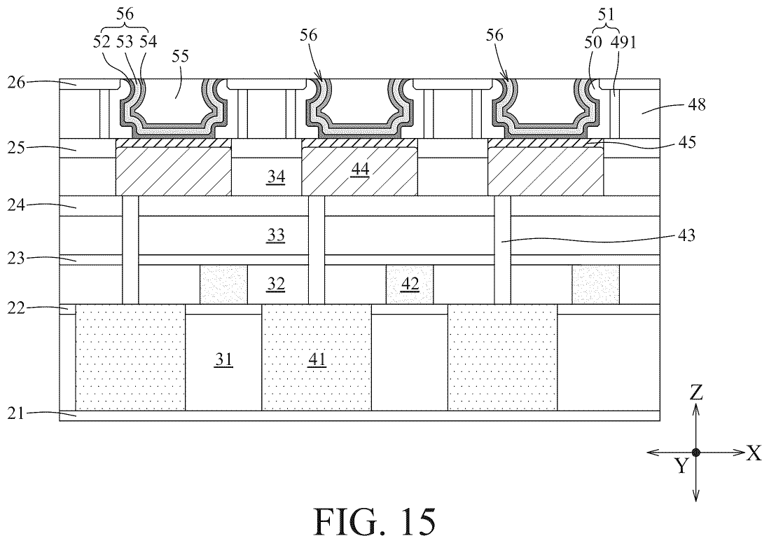

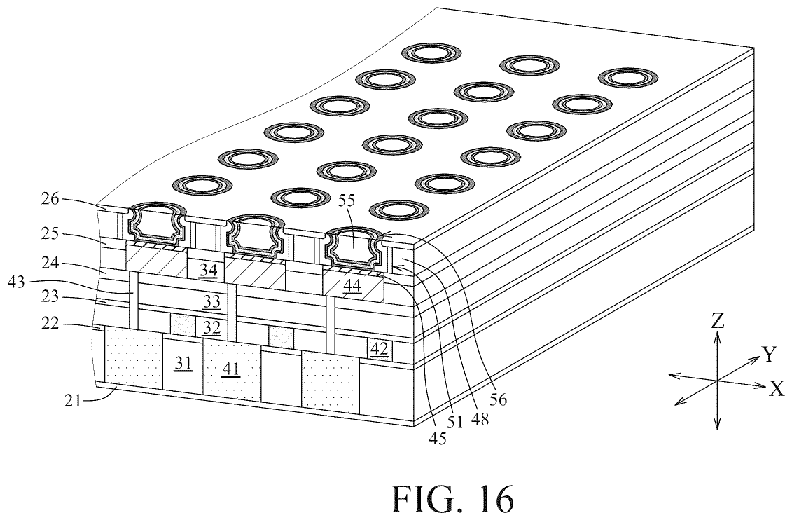

Referring to FIGS. 15 and 16, isolation elements 55 are formed to fill the cavities 510 (see FIG. 14) respectively, and channel units 56 are obtained.

In some embodiments, the isolation elements 55 are formed by: forming an isolation material layer (not shown) over the structure shown in FIG. 14; and performing a planarization process (e.g., CMP, but is not limited thereto). In the planarization process, the isolation material layer, the outer channel material layer 520, the middle channel material layer 530 and the inner channel material layer 540 are formed into the isolation elements 55, outer channel layers 52, middle channel layers 53, and inner channel layers 54, respectively. Each of the channel units 56 includes one of the outer channel layers 52, a corresponding one of the middle channel layers 53, and a corresponding one of the inner channel layers 54. In some embodiments, each of the channel units 56 has a thickness ranging from about 2 nm to about 40 nm, such as larger than 0 nm and less than about 10 nm, but is not limited thereto. In certain embodiments, the thickness of each of the channel units 56 may range from about 5 nm to about 15 nm, from about 10 nm to about 20 nm, from about 15 nm to about 25 nm, from about 20 nm to about 30 nm, from about 25 nm to about 35 nm, or from about 30 nm to about 40 nm. Each of the channel units 56 surrounds a corresponding one of the isolation elements 55. In addition, each of the channel units 56 is formed along an inner surface of a respective one of the gate structures 51 and on a top surface of a respective one of the lower electrode units. In some embodiments, a projection of each of the channel units 56 on the base structure (i.e., the structure shown in FIG. 3) overlaps with a projection of the respective gate structure 51 on the base structure. After the planarization process, in each of the channel units 56, each of the outer channel layer 52, the middle channel layer 53, and the inner channel layer 54 has a substantially U-shaped cross section along a vertical plane (perpendicular to the X and Y directions). Upper ends of the outer channel layer 52, the middle channel layer 53, and the inner channel layer 54 are exposed from the ESL 26 and a corresponding one of the isolation elements 55, and are flush with each other. Step 104 in the flow diagram shown in FIG. 1 is exemplified by the structures shown in FIGS. 14 to 16.

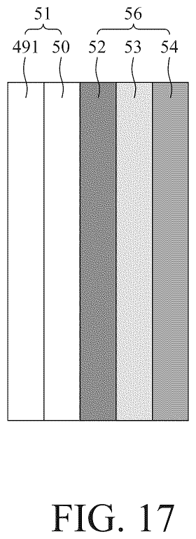

FIG. 17 is a schematic view illustrating one of the gate structures 51, and a corresponding one of the channel unit 56 in accordance with some embodiments. In the following description regarding FIG. 17, the channel units 56 and the gate structures 51 are each described in singular form for the sake of brevity. As shown in FIG. 17, the outer channel layer 52 is most proximal to the gate structure 51, while the inner channel layer 54 is most distal from the gate structure 51. In each of the channel units 56, the outer channel layer 52, the middle channel layer 53 and the inner channel layer 54 have different compositions. In accordance with some embodiments, each of the outer channel layer 52, the middle channel layer 53 and the inner channel layer 54 exemplarily includes indium gallium zinc oxide (IGZO, but is not limited thereto); however, a gallium content, and/or an indium content, and/or carrier concentrations in the three channel layers 52, 53, 54 are different.

For instance, in some embodiments, the channel unit 56 is configured to be an n-type channel unit, and a gallium content of the channel unit 56 increases in a direction away from the gate structure 51. That is, the outer channel layer 52 has the lowest gallium content and the highest carrier concentration; the middle channel layer 53 has an intermediate gallium content and an intermediate carrier concentration; and the inner channel layer 54 has the highest gallium content and the lowest carrier concentration. In some embodiments, for the outer channel layer 52, gallium is present in an amount ranging from about 0 atomic percentage to about 50 atomic percentage based on 100 atomic percentage of the metal oxide present in the outer channel layer 52. For the middle channel layer 53, gallium is present in an amount ranging from about 30 atomic percentage to about 80 atomic percentage based on 100 atomic percentage of the metal oxide present in the middle channel layer 53. For the inner channel layer 54, gallium is present in an amount ranging from about 60 atomic percentage to about 100 atomic percentage based on 100 atomic percentage of the metal oxide present in the inner channel layer 54. The difference in gallium content between two adjacent ones of the outer channel layer 52, the middle channel layer 53, and the inner channel layer 54 may range from about 15 atomic percentage to about 20 atomic percentage, so as to achieve a desired difference in etching rate. In other embodiments, the outer channel layer 52 has a carrier concentration ranging from about 1×10¹⁸ cm⁻³ to about 1×10⁻²⁰ cm⁻³; the middle channel layer 53 has a carrier concentration ranging from about 1×10¹⁵ cm⁻³ to about 1×10¹⁸ cm⁻³; and the inner channel layer 54 has a carrier concentration ranging from about 1×10¹² cm⁻³ to about 1×10¹⁵ cm⁻³. It is noted that, in IGZO, the carrier concentration is proportional to an indium content, and is inversely proportional to the gallium content. In certain embodiments, the outer channel layer 52 has the highest indium content and the highest carrier concentration; the middle channel layer 53 has an intermediate indium content and an intermediate carrier concentration; and the inner channel layer 54 has the lowest indium content and the lowest carrier concentration. Other suitable gallium content ranges and carrier concentration ranges for each of the outer channel layer 52, the middle channel layer 53, and the inner channel layer 54 are within the contemplated scope of the present disclosure.

In yet other embodiments, types of metal oxide present in each of the outer channel layer 52, the middle channel layer 53, and the inner channel layer 54 may be different. For instance, in accordance with some embodiments, the outer channel layer 52 (having the lowest gallium content) may include or be made of indium gallium zinc oxide (IGZO), zinc oxide (ZnO), indium oxide (In₂O₃), tin oxide (SnO₂), indium zinc oxide (IZO) or combinations thereof, while the inner channel layer 54 (having the highest gallium content) may include or be made of gallium oxide (GaO), indium gallium oxide (IGO), or a combination thereof. In some embodiments, the middle channel layer 53 may include a portion of the material for forming the outer channel layer 52 and a portion of the material for forming the inner channel layer 54, so as to have a gallium content between those of the inner and outer channel layers 52, 54.

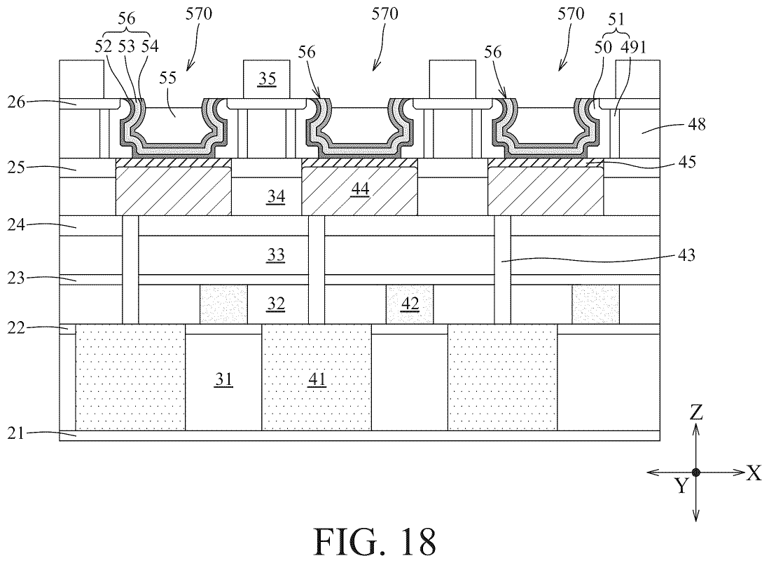

Referring to FIG. 18, a patterned ILD 35 is formed, and the isolation elements 55 are recessed.

In some embodiments, an ILD material layer (not shown, for forming the patterned ILD 35) is formed over the structure shown in FIG. 15 by a suitable deposition process. Then, a patterning process (including one or multiple etching processes) is performed to form openings 570 that expose the channel units 56, respectively. In some embodiments, the isolation elements 55 and the ILD material layer are made of a same material (e.g., silicon oxide, but is not limited thereto). During the patterning process of the ILD material layer, the isolation elements 55 are also recessed. It is noted that after the patterning process, the outer channel layer 52, the middle channel layer 53, and the inner channel layer 54 remain substantially intact, and are flush with each other.

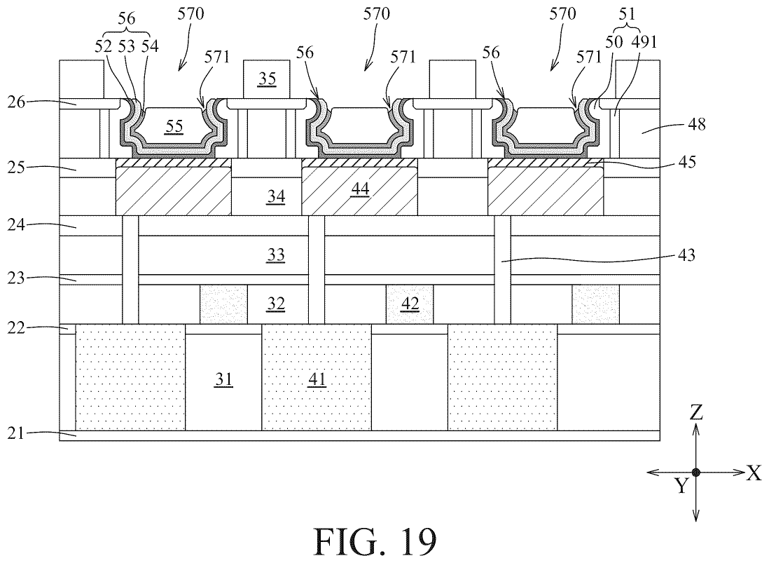

Referring to FIG. 19, a recessing process is performed on the channel units 56, such that top surfaces of the channel units 56 are recessed.

The recessing process may include any suitable processes, such as wet etching, or dry etching, or a combination thereof, but are not limited thereto. In some embodiments, one or more etching processes may be performed. As aforementioned in the description with reference to FIG. 17, in each of the channel units 56, the outer channel layer 52, the middle channel layer 53, and the inner channel layer 54 are formed with different compositions, and exhibit different etching rates in the recessing process, and thus are recessed to different extents. Specifically, after the recessing process, levels of upper ends of the outer channel layer 52, the middle channel layer 53, and the inner channel layer 54 descend in such order. The outer channel layer 52, which is most proximal to the gate structure 51, is least recessed (i.e., a majority of the outer channel layer 52 remains) to have a relatively large contact area with the gate structure 51, so that the gate structure 51 can better control the channel unit 56. The etching rate of the inner channel layer 54 is higher than the etching rate of the middle channel layer 53 by about 5 times to about 10 times. The etching rate of the middle channel layer 53 is higher than the etching rate of the outer channel layer 52 by about 5 times to about 10 times. Such difference in etching rates facilitates the different levels of the upper ends of different channel layers 52, 53, 54. In addition, after the recessing processing, spaces 571 are formed above the channel units 56, respectively. Each of the spaces 571 is in spatial communication with a corresponding one of the openings 570. Step 105 in the flow diagram shown in FIG. 1 is exemplified by the structures shown in FIGS. 18 and 19.

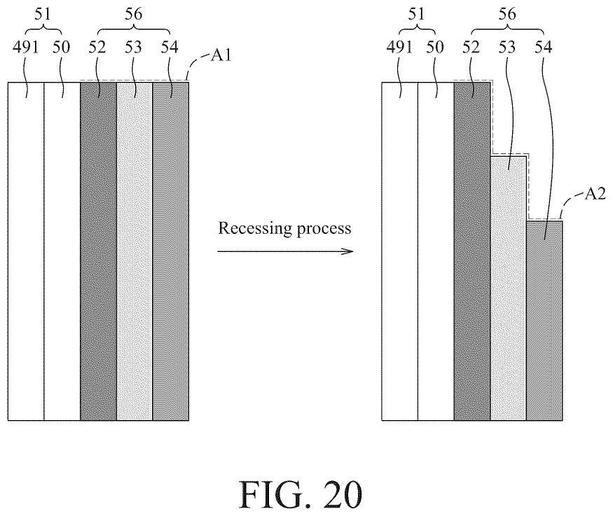

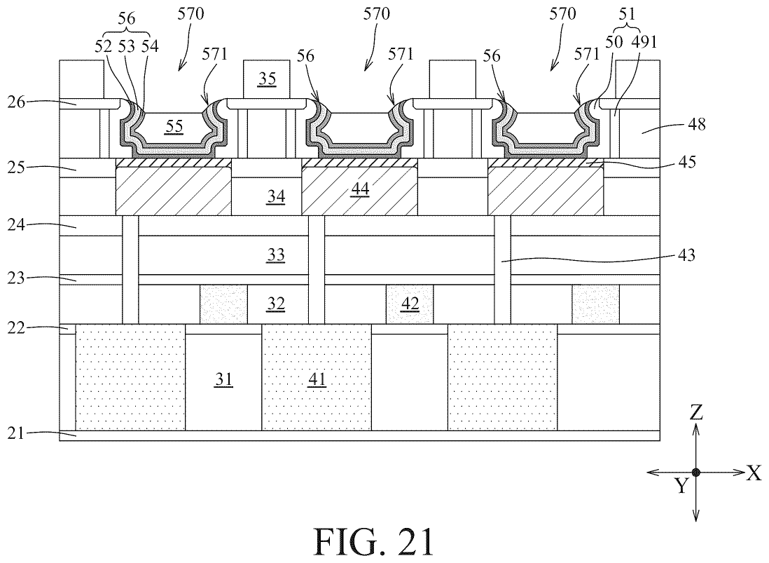

FIG. 20 is a schematic view of one of the gate structures 51, and a corresponding one of the channel units 56 before and after the recessing process. In the following description regarding FIGS. 20 and 21, the channel units 56 and the gate structures 51 are each described in singular form for the sake of brevity.

Exemplarily, in accordance with some embodiments, the outer channel layer 52, which is located closest to the gate structure 51, and which has the lowest gallium content, has the lowest etching rate. A majority of the outer channel layer 52 remains after the recessing process, resulting in the upper end of the outer channel layer 52 being located at the highest level compared with those of the middle channel layer 53 and the inner channel layer 54. The inner channel layer 54, which is located furthest from the gate structure 51, and which has the highest gallium content, has the highest etching rate. An amount of the inner channel layer 54 which remains is much smaller, resulting in the upper end of the inner channel layer 54 being located at the lowest level compared with those of the outer channel layer 52 and the middle channel layer 53. The middle channel layer 53, which is located between the outer channel layer 52 and the inner channel layer 54, and which has the intermediate gallium content, has an intermediate etching rate. An amount of the middle channel layer 53 which remains is greater than that of the inner channel layer 54, and is less than that of the outer channel layer 52, and thus the upper end of the middle channel layer 53 is at a level between those of the upper end of the outer channel layer 52 and the upper end of the inner channel layer 54. As such, a top surface of the recessed channel unit 56 descends in a direction away from the gate structure 51 toward a corresponding one of the isolation elements 55 (see also FIG. 19). After the recessing process, a top surface area (see the top surface encompassed by the line that is denoted by A2 in FIG. 20) of the recessed channel unit 56 is significantly increased in comparison with a top surface area (see the top surface encompassed by the line that is denoted by A1 in FIG. 20) of the channel unit 56 before the recessing process.

In some embodiments, a wet etching process is adopted to better control etching selectivity to the different channel layers (i.e., the different channel layers have different etching rates). FIG. 19 shows a profile of the recessed channel unit 56 after the wet etching process. It is noted that the inner channel layer 54 is recessed at an extent that is relatively greater than those of the middle channel layer 53 and the outer channel layer 52. The space 571 is formed with a relatively large size, and the top surface of the channel unit 56 has a relatively steep slope.

In some other embodiments, a dry etching process may also be adopted. FIG. 21 shows a profile of the recessed channel unit 56 after the dry etching process. It is noted that the outer channel layer 52, the middle channel layer 53, and the inner channel layer 54 exhibit more consistent etching rates. The space 571 is formed with a relatively small size, and the top surface of the channel unit 56 has a relatively moderate slope.

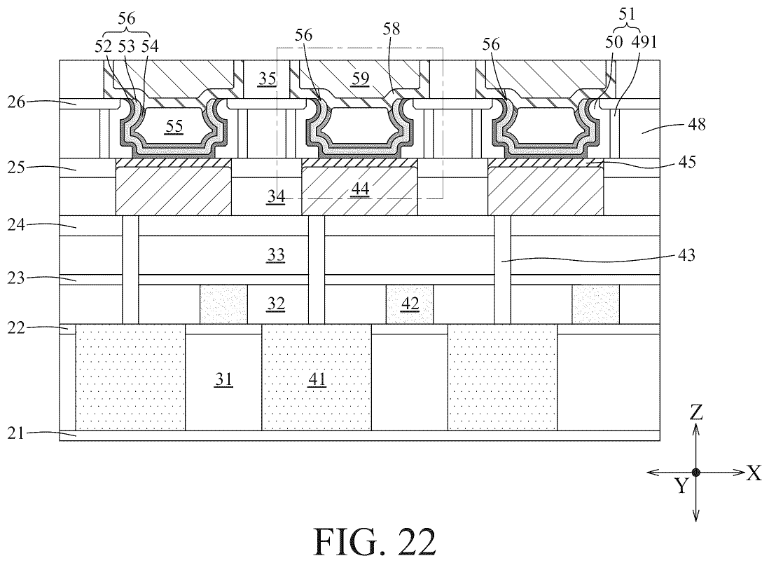

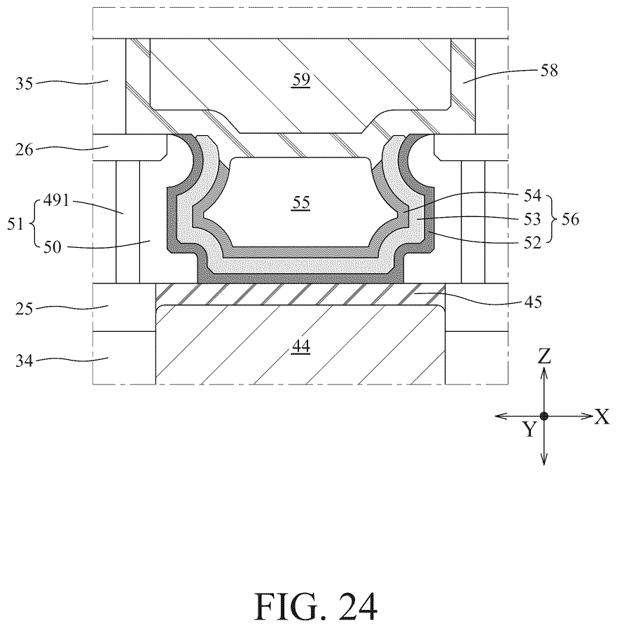

Referring to FIGS. 22 to 24, upper electrode units are formed in the openings 570, respectively. In some embodiments, hydrogen absorption layers 58 are formed, and upper electrodes 59 are formed on the hydrogen absorption layers 58, respectively. In other words, each of the upper electrode units includes one of the hydrogen absorption layers 58 and a respective one of the upper electrodes 59. FIG. 24 is an enlarged view of a region framed by a dotted line in FIG. 22.

The hydrogen absorption layers 58 may include a material similar to that of the hydrogen absorption layers 45. The hydrogen absorption layers 58 may be formed in a conformal manner along the inner surfaces of the openings 570, and fill the spaces 571, respectively (see also FIGS. 19 and 21). As such, the hydrogen absorption layers 58 are each connected to a corresponding one of the channel units 56. In the present disclosure, the channel units 56 are recessed such that the top surfaces thereof have increased surface area. As such, a contact surface area between each of the channel unit 56 and a corresponding one of the hydrogen absorption layers 58 is significantly increased (in comparison with the case where the channel unit 56 is not subjected to the recessing process), which is conducive to reduce contact resistance therebetween, and thus performance of a device, such as a device current of the semiconductor structure 100, is improved. As shown in FIG. 24, each of the upper electrode units has a lower portion surrounded by a respective one of the channel units 56, and an upper portion located above the respective channel unit 56. Specifically, each of the upper electrode units has a lowest point that is located at a level lower than a level of a highest point of the respective channel unit 56, relative to a respective one of the lower electrode units.

The upper electrodes 59 are configured as another source/drain electrodes, depending on product designs. In accordance with some embodiments, the upper electrodes 59 serve as drain electrodes of the semiconductor structure 100, and are connected to bit lines (e.g., conductive features 60 shown in FIGS. 26 to 29). In other embodiments, the upper electrodes 59 may also serve as source electrodes, and are connected to the memory elements 41 (one of which is shown in FIGS. 30 and 31). The upper electrodes 59 may include a material similar to those of the lower electrodes 44 described with reference to FIG. 6, and thus description of the material are omitted for the sake of brevity.

In other embodiments, the hydrogen absorption layers 58 may be omitted, and the upper electrodes 59 are directly connected to the channel units 56, respectively. In such case, similar to the case that the hydrogen absorption layers 58 is present in the upper electrode unit, a contact surface area between each of the recessed channel unit 56 and a corresponding one of the upper electrodes 59 is significantly increased, so that a contact resistance is reduced, and device performance is improved.

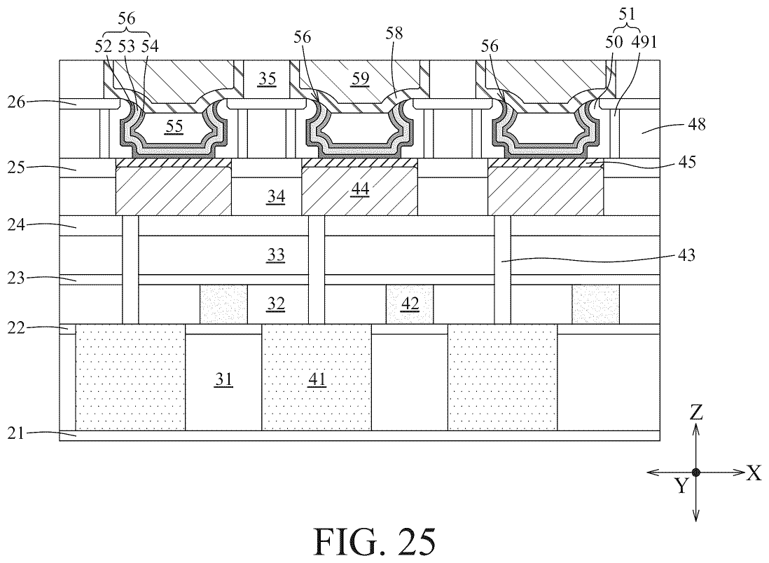

FIG. 22 shows a profile of the recessed channel units 56, and the upper electrode units in accordance with some embodiments, in which the channel units 56 are recessed using the wet etching process. FIG. 25 shows a profile similar to that of FIG. 22 but illustrates a configuration where the channel units 56 are recessed using the dry etching process. As shown by both profiles, the upper electrode units fill the spaces 571 (see FIGS. 19 and 21) and have a larger contact surface area with the channel units 56.

Referring to FIG. 26, conductive elements 60 are formed.

The conductive elements 60 are formed by: forming an ILD 36 over the structure shown in FIG. 22 using a suitable deposition process; performing a patterning process to form trenches (not shown) exposing the upper electrode units; forming a conductive material layer (not shown, for forming the conductive elements 60) over the ILD 36 to fill the trenches; and performing a planarization process to remove and excess amount of the conductive material layer, thereby forming the conductive elements 60. The conductive elements 60 may include or be made of a material similar to that of the conductive elements 42, and thus details thereof are omitted for the sake of brevity. Other suitable materials and/or processes for forming the conductive elements 60 are within the contemplated scope of the present disclosure.

The conductive elements 60 are each configured to connect corresponding ones of the upper electrodes 59. In accordance with some embodiments, referring to FIGS. 26 to 29, the conductive elements 60 may each serve as a bit line (BL).

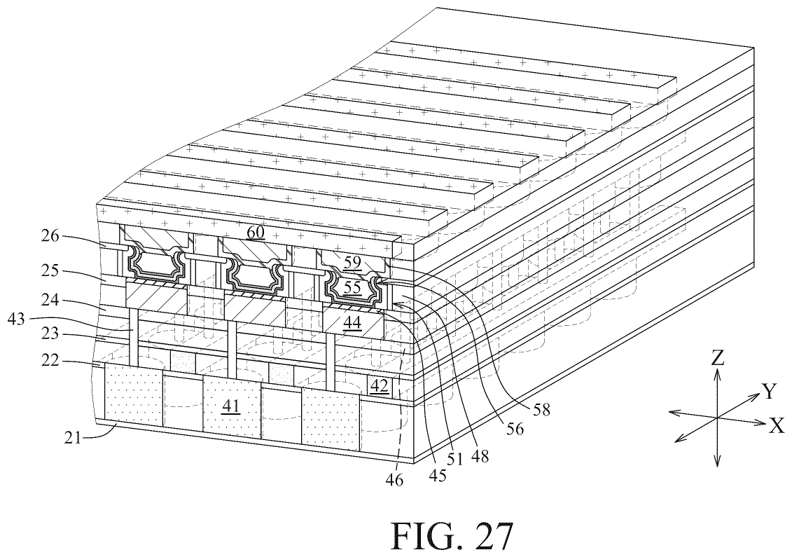

The semiconductor structure 100 of the present disclosure is obtained and shown in FIG. 26. FIG. 27 is similar to FIG. 26 by showing interior and connections of different elements within the semiconductor structure 100. The channel units 56 are each surrounded by a corresponding one of the gate structures 51, and are each connected to a respective one of the upper electrodes 59, and a respective one of the lower electrodes 44. The gate electrodes 491 of the gate structures 51 (see FIG. 22 or 25) are each connected to a respective one of the conductive elements 42 (each serves as a word line) through a respective one of the vias 46 (see FIG. 8). The upper electrodes 59 (each serves as a drain) are each connected to a corresponding one of the conductive elements 60 (each serves as a bit line). The lower electrodes 44 (each serves as a source) are each connected to a respective one of the memory elements 41 (e.g., a capacitor, but is not limited thereto) through a respective one of the vias 43.

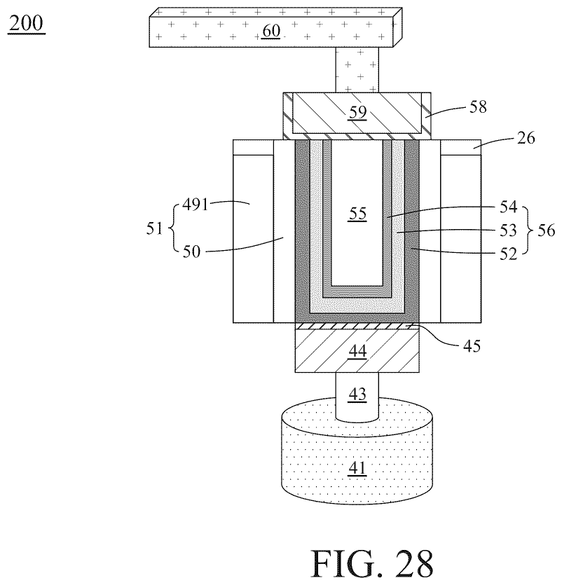

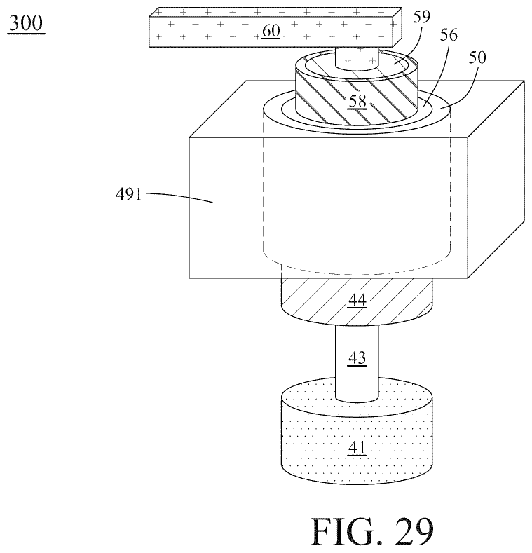

FIG. 28 is a schematic diagram of a semiconductor structure 200 in accordance with some embodiments. The semiconductor structure 200 is similar to a semiconductor structure 100 shown in FIG. 26, but FIG. 28 illustrates merely one channel unit 56 and one gate structure 51, and the top surface of the channel unit 56 is drawn without showing the recessed profile. In the semiconductor structure 200, the channel unit 56 and the gate structure 51 has a cylindrical shape. A projection of the channel unit 56 on the base structure (e.g., the structure shown in FIG. 3) is displaced from a projection of the gate structure 51 on the base structure. FIG. 29 is a perspective view of a semiconductor structure 300 in accordance with some embodiments. In FIG. 29, the semiconductor structure 300 is similar to the semiconductor structure 200, except that the upper electrode unit covers an inner peripheral portion of the channel unit 56, while an outer peripheral portion of the channel unit 56 is uncovered by the upper electrode unit.

FIG. 30 is a schematic diagram of a semiconductor structure 400 in accordance with some embodiments. FIG. 31 is a perspective view of a semiconductor structure 500 in accordance with some embodiments. The semiconductor structures 400 and 500 shown in FIGS. 30 and 31 are respectively similar to the semiconductor structures 200 and 300 shown in FIGS. 28 and 29. Different from the semiconductor structures 200 and 300, in each of the semiconductor structures 400 and 500, the upper electrode 59 serves as the source electrode, while the lower electrode 44 serves as the drain electrode. In this case, the conductive element 60, i.e., the bit line, is formed before forming the lower electrode 44, and the memory element 41 is formed after forming the upper electrode 59. In some embodiments, the bit line, i.e., the conductive element 60, is further connected to an underlying logic element, e.g., the semiconductor device 2 shown in FIG. 2. By forming the conductive element 60 first and closer to the underlying logic element, a shallow via (not shown) may be used to connect the conductive element 60 and the underlying logic element. Such configuration may help save area for forming the structures as described, and thus enable a high density of the structure under a certain chip size.

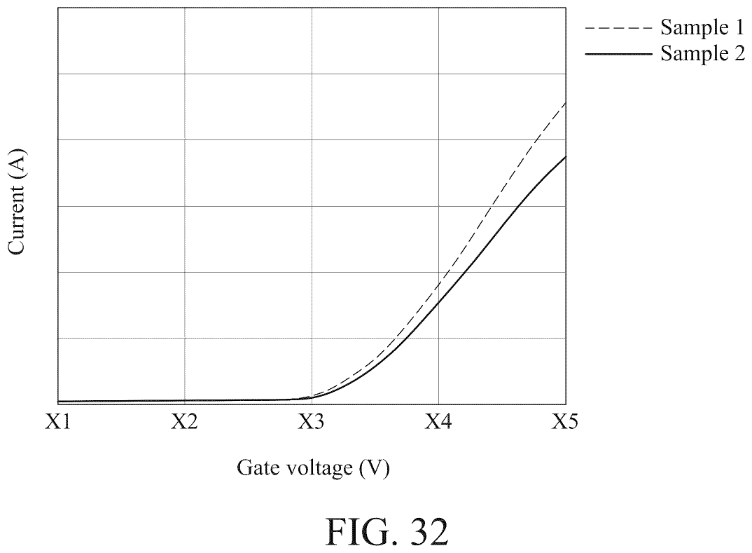

FIG. 32 shows comparison of results obtained with and without performing the recessing process, i.e., step 105, in the method of the present disclosure. Sample 1 is a semiconductor structure prepared in accordance with the aforementioned method, in which the channel unit is recessed to have a recessed top surface. Sample 2 is a semiconductor structure similar to sample 1, except that the channel unit of sample 2 is not subjected to any recessing process, and has a relatively flat top surface (compared with that of sample 1). As shown in FIG. 32, with regard to gate voltages (Vg), X1<X2<X3<4<X5, and a same gate voltage (Vg) is applied simultaneously to each of the samples 1 and 2, followed by determining currents of the samples 1 and 2. It is noted that both samples 1 and 2 have similar threshold voltage. As shown in FIG. 32, sample 1 exhibits a current larger than that of sample 2 when the gate voltage is larger than the threshold voltage. These results indicate performing the recessing process on the channel unit is effective to increase surface area of the top surface of the channel unit, and to reduce the contact resistance between the recessed channel unit and the upper electrode, so that a larger current is detected.

The embodiments of the present disclosure have the following advantageous features. The channel unit 56 is first formed with at least two channel layers, e.g., the outer channel layer 52, the middle channel layer 53, the inner channel layer 54, that have different compositions. A recessing process is then performed on the channel unit 56. In the recessing process, the outer, middle and inner channel layers 52, 53, 54 have different etching rates, and are recessed to different extents. As such, a top surface of the channel unit 56 is formed with a relatively large surface area, which enables formation of a large contact surface area between the channel unit 56 and the upper electrode unit (i.e., the upper electrode 59 and the hydrogen absorption layer 58). Thus, contact resistance between the channel unit 56 and the upper electrode unit is significantly reduced, and performance of the semiconductor structure is therefore enhanced, e.g., having an increased current.

In accordance with some embodiments of the present disclosure, a method for manufacturing a semiconductor structure includes: forming a lower electrode unit on a base structure; forming a gate structure over the lower electrode unit, the gate structure being formed with a cavity above the lower electrode unit; forming a channel unit, which includes forming an outer channel layer and an inner channel layer along an inner surface of the cavity, the outer channel layer and the inner channel layer having different compositions; performing a recessing process on the channel unit, and after the recessing process, an upper end of the outer channel layer being located at a level higher than a level of an upper end of the inner channel layer; and after the recessing process, forming an upper electrode unit connected to both the outer channel layer and the inner channel layer.

In accordance with some embodiments of the present disclosure, forming the channel unit further includes forming a middle channel layer between the outer channel layer and the inner channel layer, a composition of the middle channel layer being different from the composition of the inner channel layer and the composition of the outer channel layer, after the recessing process, an upper end of the middle channel layer is located at a level between the upper end of the outer channel layer and the upper end of the inner channel layer, and the upper electrode unit is formed to be connected to the outer channel layer, the inner channel layer, and the middle channel layer.

In accordance with some embodiments of the present disclosure, the method further includes forming an isolation element surrounded by the channel unit.

In accordance with some embodiments of the present disclosure, forming the isolation element, the outer channel layer, and the inner channel layer includes: sequentially forming an outer channel material layer and an inner channel material layer along the inner surface of the cavity; forming an isolation material layer over the inner material layer in the cavity; and performing a planarization process such that the outer channel material layer, the inner channel material layer, and the isolation material layer are formed into the outer channel layer, the inner channel layer, and the isolation element, respectively.

In accordance with some embodiments of the present disclosure, the method further includes forming a patterned interlayer dielectric over the channel unit after forming the channel unit and the isolation element, and before performing the recessing process, wherein the channel unit is exposed from the patterned interlayer dielectric, and wherein in forming the patterned interlayer dielectric, the isolation element is recessed.

In accordance with some embodiments of the present disclosure, a gallium content of the inner channel layer is higher than a gallium content of the outer channel layer, in the recessing process, an etching rate of the inner channel layer being greater than an etching rate of the outer channel layer.

In accordance with some embodiments of the present disclosure, a carrier concentration of the outer channel layer is higher than a carrier concentration of the inner channel layer, in the recessing process, an etching rate of the inner channel layer being greater than an etching rate of the outer channel layer.

In accordance with some embodiments of the present disclosure, forming the gate structure includes: forming a sacrificial part on and covering the lower electrode unit; forming an isolation layer surrounding the sacrificial part, the isolation layer being spaced apart from the sacrificial part by a gap; forming a gate electrode in the gap; removing the sacrificial part to form the cavity; and forming a gate dielectric layer along the inner surface of the cavity, the lower electrode unit being exposed from the gate dielectric layer.

In accordance with some embodiments of the present disclosure, the channel unit includes indium gallium zinc oxide, zinc oxide, indium oxide, tin (IV) oxide, indium zinc oxide, gallium oxide, indium gallium oxide, nickel oxide, copper oxide, copper aluminum oxide, copper gallium oxide, copper indium oxide, strontium copper oxide, tin (II) oxide, or combinations thereof.

In accordance with some embodiments of the present disclosure, the channel unit is doped with nitrogen, fluorine, aluminum, hafnium, magnesium, silicon, titanium, tungsten, yttrium, zirconium, boron, hydrogen, lithium, nickel, potassium, rubidium, phosphorus, tantalum, sulphur, sodium, cesium, germanium, or combinations thereof.

In accordance with some embodiments of the present disclosure, a method for manufacturing a semiconductor structure includes: forming a lower source/drain electrode unit on a base structure; forming a gate structure over the lower source/drain electrode unit, the gate structure being formed with a cavity above the lower source/drain electrode unit; forming a channel unit, which includes forming an outer channel layer and an inner channel layer along an inner surface of the cavity, the outer channel layer and the inner channel layer having different compositions; performing a recessing process to the channel unit, an etching rate of the inner channel layer in the recessing process being greater than an etching rate of the outer channel layer; and after the recessing process, forming an upper source/drain electrode unit connected to both the outer channel layer and the inner channel layer.

In accordance with some embodiments of the present disclosure, the etching rate of the inner channel layer in the recessing process is greater than an etching rate of the outer channel layer by at least 5 times.

In accordance with some embodiments of the present disclosure, the inner channel layer has a first gallium atomic percentage, and the outer channel layer has a second gallium atomic percentage, the first gallium atomic percentage being greater than the second gallium atomic percentage by at least 15 atomic percentage.

In accordance with some embodiments of the present disclosure, the inner channel layer includes gallium oxide, or indium gallium oxide, and the outer channel layer includes indium gallium zinc oxide, zinc oxide, indium oxide, tin oxide, or indium zinc oxide.

In accordance with some embodiments of the present disclosure, a projection of the channel unit on the base structure is displaced from a projection of the gate structure on the base structure.

In accordance with some embodiments of the present disclosure, a projection of the channel unit on the base structure overlaps with a projection of the gate structure on the base structure.

In accordance with some embodiments of the present disclosure, the upper electrode unit has a lower portion surrounded by the channel unit, and an upper portion located above the channel unit.

In accordance with some embodiments of the present disclosure, the method further includes forming an isolation element surrounded by the channel unit prior to the recessing process, after the recessing process, a top surface of the channel unit descends in a direction away from the gate structure toward the isolation element.

In accordance with some embodiments of the present disclosure, a semiconductor structure includes: a lower electrode unit and an upper electrode unit disposed on a base structure, a gate structure, and a channel unit. The gate structure is disposed between the lower electrode unit and the upper electrode unit. The channel unit is surrounded by the gate structure and connected to the lower electrode unit and the upper electrode unit. The channel unit includes an outer channel layer and an inner channel layer. The outer channel layer is formed on and along an inner surface of the gate structure and a top surface of the lower electrode unit. The inner channel layer is formed on the outer channel layer opposite to the gate structure and the lower electrode unit. A composition of the inner channel layer is different from a composition of the outer channel layer, and an upper end of the outer channel layer is located at a level higher than a level of an upper end of the inner channel layer.

In accordance with some embodiments of the present disclosure, the channel unit further includes a middle channel layer that is located between the outer channel layer and the inner channel layer. The middle channel layer has a composition different from the composition of the inner channel layer and the composition of the outer channel layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a lower electrode unit on a base structure;
forming a gate structure over the lower electrode unit, the gate structure being formed with a cavity above the lower electrode unit;
forming a channel unit, which includes forming an outer channel layer and an inner channel layer along an inner surface of the cavity, the outer channel layer and the inner channel layer having different compositions;
performing a recessing process on the channel unit, and after the recessing process, an upper end of the outer channel layer being located at a level higher than a level of an upper end of the inner channel layer; and
after the recessing process, forming an upper electrode unit connected to both the outer channel layer and the inner channel layer.

2. The method of claim 1, wherein:
forming the channel unit further includes forming a middle channel layer between the outer channel layer and the inner channel layer, a composition of the middle channel layer being different from the composition of the inner channel layer and the composition of the outer channel layer,
after the recessing process, an upper end of the middle channel layer is located at a level between the upper end of the outer channel layer and the upper end of the inner channel layer, and
the upper electrode unit is formed to be connected to the outer channel layer, the inner channel layer, and the middle channel layer.

3. The method of claim 1, further comprising forming an isolation element surrounded by the channel unit.

4. The method of claim 3, wherein forming the isolation element, the outer channel layer, and the inner channel layer includes:
sequentially forming an outer channel material layer and an inner channel material layer along the inner surface of the cavity;
forming an isolation material layer over the inner material layer in the cavity; and
performing a planarization process such that the outer channel material layer, the inner channel material layer, and the isolation material layer are formed into the outer channel layer, the inner channel layer, and the isolation element, respectively.

5. The method of claim 3, further comprising forming a patterned interlayer dielectric over the channel unit after forming the channel unit and the isolation element, and before performing the recessing process,
wherein the channel unit is exposed from the patterned interlayer dielectric, and
wherein in forming the patterned interlayer dielectric, the isolation element is recessed.

6. The method of claim 1, wherein a gallium content of the inner channel layer is higher than a gallium content of the outer channel layer,
in the recessing process, an etching rate of the inner channel layer being greater than an etching rate of the outer channel layer.

7. The method of claim 1, wherein a carrier concentration of the outer channel layer is higher than a carrier concentration of the inner channel layer,
in the recessing process, an etching rate of the inner channel layer being greater than an etching rate of the outer channel layer.

8. The method of claim 1, wherein forming the gate structure includes:
forming a sacrificial part on and covering the lower electrode unit;
forming an isolation layer surrounding the sacrificial part, the isolation layer being spaced apart from the sacrificial part by a gap;
forming a gate electrode in the gap;
removing the sacrificial part to form the cavity; and
forming a gate dielectric layer along the inner surface of the cavity, the lower electrode unit being exposed from the gate dielectric layer.

9. The method of claim 1, wherein the channel unit includes indium gallium zinc oxide, zinc oxide, indium oxide, tin (IV) oxide, indium zinc oxide, gallium oxide, indium gallium oxide, nickel oxide, copper oxide, copper aluminum oxide, copper gallium oxide, copper indium oxide, strontium copper oxide, tin (II) oxide, or combinations thereof.

10. The method of claim 1, wherein the channel unit is doped with nitrogen, fluorine, aluminum, hafnium, magnesium, silicon, titanium, tungsten, yttrium, zirconium, boron, hydrogen, lithium, nickel, potassium, rubidium, phosphorus, tantalum, sulphur, sodium, cesium, germanium, or combinations thereof.

11. A method for manufacturing a semiconductor structure, comprising:
forming a lower source/drain electrode unit on a base structure;
forming a gate structure over the lower source/drain electrode unit, the gate structure being formed with a cavity above the lower source/drain electrode unit;
forming a channel unit, which includes forming an outer channel layer and an inner channel layer along an inner surface of the cavity, the outer channel layer and the inner channel layer having different compositions;
performing a recessing process to the channel unit, an etching rate of the inner channel layer in the recessing process being greater than an etching rate of the outer channel layer; and
after the recessing process, forming an upper source/drain electrode unit connected to both the outer channel layer and the inner channel layer.

12. The method of claim 11, wherein the etching rate of the inner channel layer in the recessing process is greater than an etching rate of the outer channel layer by at least 5 times.

13. The method of claim 11, wherein the inner channel layer has a first gallium atomic percentage, and the outer channel layer has a second gallium atomic percentage, the first gallium atomic percentage being greater than the second gallium atomic percentage by at least 15 atomic percentage.

14. The method of claim 11, wherein the inner channel layer includes gallium oxide, or indium gallium oxide, and the outer channel layer includes indium gallium zinc oxide, zinc oxide, indium oxide, tin oxide, or indium zinc oxide.

15. The method of claim 11, wherein a projection of the channel unit on the base structure is displaced from a projection of the gate structure on the base structure.

16. The method of claim 11, wherein a projection of the channel unit on the base structure overlaps with a projection of the gate structure on the base structure.

17. The method of claim 11, wherein the upper electrode unit has a lower portion surrounded by the channel unit, and an upper portion located above the channel unit.

18. The method of claim 11, further comprising forming an isolation element surrounded by the channel unit prior to the recessing process,
after the recessing process, a top surface of the channel unit descends in a direction away from the gate structure toward the isolation element.

19. A semiconductor structure, comprising:
a lower electrode unit and an upper electrode unit disposed on a base structure;
a gate structure disposed between the lower electrode unit and the upper electrode unit; and
a channel unit surrounded by the gate structure and connected to the lower electrode unit and the upper electrode unit, the channel unit including:
an outer channel layer formed on and along an inner surface of the gate structure and a top surface of the lower electrode unit; and
an inner channel layer formed on the outer channel layer opposite to the gate structure and the lower electrode unit,
wherein a composition of the inner channel layer is different from a composition of the outer channel layer, and an upper end of the outer channel layer is located at a level higher than a level of an upper end of the inner channel layer.

20. The semiconductor structure of claim 19, wherein the channel unit further includes a middle channel layer that is located between the outer channel layer and the inner channel layer, the middle channel layer having a composition different from the composition of the inner channel layer and the composition of the outer channel layer.
